(19) United States
(12) Patent Application Publication
(10) Pub. No.: US 2004/0018742 A1
(43) Pub. Date: Jan. 29, 2004

(54) Forming bilayer resist patterns

(75) Inventors: Jim Zhongyi He, Sunnyvale, CA (US); Meihua Shen, Fremont, CA (US); Hong Du, Cupertino, CA (US); Scott M. Williams, Sunnyvale, CA (US)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/379,980

(22) Filed: Mar. 4, 2003

Related U.S. Application Data
(60) Provisional application No. 60/398,892, filed on Jul. 25, 2002.

(51) Int. Cl. H01L 21/302; H01L 21/461

(52) U.S. Cl. 438/710

(57) ABSTRACT

The present invention includes a method for patterning a bilayer resist having a patterned upper resist layer over a lower resist layer formed on a substrate. In one embodiment of the present invention, the method includes an optional upper resist layer trimming step, an upper resist layer treatment step, and a lower resist layer etching step. In the upper resist layer trimming step, the upper resist layer is trimmed in a plasma of a first process gas. In the upper resist layer treatment step, the upper resist layer is treated in a plasma of a second process gas to increase its etch resistance during the subsequent lower resist layer etching step. In the lower resist etching step, the lower resist layer is etched in a plasma of a third process gas, using the upper resist layer as a mask.

This application claims priority of provisional application serial No. 60/398,892 filed on Jul. 25, 2002.

The present application relates to semiconductor processing technology and particularly to forming patterns in bilayer resist films.

### BACKGROUND

The performance of today's integrated circuit chips is directly related to the dimensions of the transistors and wiring interconnects in the integrated circuits. As the dimensions of the transistors and wiring interconnects continue to shrink, the ability to pattern ever-smaller features using photolithography has been a primary factor driving the success of the integrated circuit fabrication industry.

Photolithography processes involve the use of lithography imaging tools and photoresist (or resist) materials. The minimum resolution achievable with a lithography imaging tool is governed by the Rayleigh diffraction limit, i.e., the minimum resolution is limited by an exposure wavelength and a resolving power or numerical aperture (NA) of a lens system used by the lithography imaging tool. A shorter exposure wavelength or a larger NA often results in higher resolution and thus the ability to print smaller patterns in a resist film. However, decreasing the wavelength or increasing the NA often results in a decrease in the depth of focus (DOF), thereby requiring a reduction in the thickness of the photoresist film.

Simply reducing the thickness of the resist film to enhance resolution is effective only up to a certain point, i.e., when the resist becomes too thin to withstand subsequent etching processes that transfer the resist pattern to one or more layers under the resist film. In order to overcome these problems, bilayer resists have been developed to extend the photolithography technology. A bilayer resist (or BLR) film typically includes a relatively thick lower resist layer (or masking layer) coated on a wafer or substrate and a relatively thin upper resist layer (or imaging layer) coated on top of the lower resist layer. The upper resist layer is patterned by light exposure and development of the upper resist layer, and the resulting upper layer pattern is used as a mask for etching the lower resist layer. In this way, a resist pattern with high aspect ratio can be formed in the BLR film.

In order to provide sufficient etch resistance to the upper resist layer when the bilayer resist undergoes a lower resist layer etching process, silicon is usually incorporated into the upper resist layer. Since the lower resist layer is typically made of organic polymers, an O₂-based plasma is usually used to etch the lower resist layer, using the patterned top resist layer as a mask. Thus, while the lower resist layer is being etched in the O₂-based plasma, silicon precursors in the upper resist layer are oxidized to form a refractory oxide during the etching processes. The refractory oxide acts as an etch barrier, resulting in enhanced etching resistance of the upper resist layer. The enhancement achieved in this manner, however, is found in many applications to be insufficient.

The lower resist etching process not only requires good etch contrast between the upper resist layer and the lower resist layer, but also needs to be anisotropic to achieve good critical dimension (CD) control. With pure O₂ plasma, however, anisotropic etching can only be achieved when the temperature of the resist layers is maintained at or below about −100° C. during the etching process. Otherwise, lateral etching or undercutting is usually observed, indicating CD loss. Adding SO₂ to the O₂-based chemistry has been found to result in improved etching anisotropy. See “Transfer Etching Of Bilayer Resists in Oxygen-Based Plasmas,” by Mahorowaia, et al, J. Vac. Sci. Technol. A 18(4), July/August 2000, p. 1441. But the use of SO₂ gas tends to cause corrosion of the equipment used for the lower resist layer etching process. Also, since SO₂ is not typically used in conventional plasma processes, adding SO₂ may require costly alteration of plasma processing equipment used in conventional integrated circuit fabrication processes.

Furthermore, to enable the patterning of small (e.g. sub-0.1 μm) features, the patterned upper resist layer sometimes needs to be trimmed to obtain desired critical dimension (CD). Trimming also helps to reduce wafer to wafer CD variations, which is a common problem with many photo lithography processes and which has become less and less tolerable with smaller and smaller CD's. Resist trimming is typically done in an O₂(or N₂)-containing plasma. Trimming of the upper layer resist is difficult because the upper resist layer is usually silicon-rich and undergoes oxidation (or nitridation) during the trimming process, forming SiO₂(or Si₄N₃)-like materials that are difficult to remove. Also, trimming of very small lines in the upper resist pattern requires the trimming process to have high linearity with a trimming time period and uniformity across the wafer. These requirements have not been met by many conventional resist trimming processes.

### SUMMARY

The present invention includes a method for patterning a bilayer resist having a patterned upper resist layer over a lower resist layer formed on a substrate. In one embodiment of the present invention, the method includes an optional upper resist layer trimming step, an upper resist layer treatment step, and a lower resist layer etching step. In the upper resist layer trimming step, the upper resist layer is trimmed in a plasma of a first process gas. The first process gas includes oxygen and a fluorine-containing gas selected from the group consisting of SF₆, SF₄, S₂F₂. S₂F₁₀, and NF₃. The first process gas may further include a bromine-containing gas selected from the group consisting of HBr, CH₃Br, and CH₂Br₂, and/or a chlorine-containing gas selected from the group consisting of Cl₂ and HCl. The plasma of the first process gas is maintained for a period of time determined from a target CD and a CD measured from the upper resist layer before trimming. During this period of time, the substrate is placed on a pedestal in a plasma etch chamber, and the plasma of the first process gas is maintained in the plasma etch chamber such that no substantial DC bias exists between the pedestal and the plasma of the first process gas.

In the upper resist layer treatment step, the upper resist layer is treated in a plasma of a second process gas to increase its etch resistance during the subsequent lower resist layer etching step. The second process gas includes oxygen and/or nitrogen, and further includes an inert gas selected from the group consisting of argon, neon, xenon, and krypton. The second process gas may further include chlorine. During the upper resist layer treatment step, the substrate is placed on a pedestal in a plasma etch chamber, and the plasma of the second process gas is maintained in the plasma etch chamber such that a substantial DC bias exists between the pedestal and the plasma of the second process gas.

In the lower resist etching step, the lower resist layer is etched in a plasma of a third process gas, using the upper resist layer as a mask. The third process gas includes O₂ and a bromine-containing gas selected from the group consisting of HBr, CH₃Br, and CH₂Br₂. The third process gas may further include N₂, and/or an inert gas selected from the group consisting of argon, neon, xenon, and krypton.

### DRAWINGS

Additional objects and features of the invention will be more readily apparent from the following detailed description and appended claims when taken in conjunction with the drawings, in which:

FIGS. 1A and 1B are schematic views in vertical cross-section of a bilayer resist before and after a bilayer resist patterning process, respectively, according to one embodiment of the present invention;

FIG. 2A is a schematic view in vertical cross-section of an exemplary plasma reactor used to practice the bilayer resist patterning process according to one embodiment of the present invention;

FIG. 2B is a flowchart illustrating a process for performing a plasma process in the exemplary plasma reactor according to one embodiment of the present invention;

FIG. 3 is a flowchart illustrating the bilayer resist patterning process according to one embodiment of the present invention;

FIGS. 4A-4D are schematic views in vertical cross section of a bilayer resist at different stages during the bilayer resist patterning process according to one embodiment of the present invention;

FIG. 5 is a flowchart illustrating a resist trimming process according to one embodiment of the present invention;

FIG. 6 is a schematic top-down view of a cluster tool for performing the resist trimming process in one embodiment of the present invention;

FIGS. 7A and 7B are schematic cross-sectional views of a bilayer resist illustrating the problems of undercutting and footing, respectively.

FIG. 8 is a chart illustrating a linear relationship between a trimming time and a CD loss during the resist trimming process in one embodiment of the present invention;

FIG. 9 is a chart illustrating uniformity of the resist trimming process in one embodiment of the present invention;

FIG. 10A is a chart showing critical aspect ratio collapse of conventional resist patterning processes;

FIG. 10B is a chart showing improvement in critical aspect ratio collapse using the resist patterning process in one embodiment of the present invention.

### DESCRIPTION

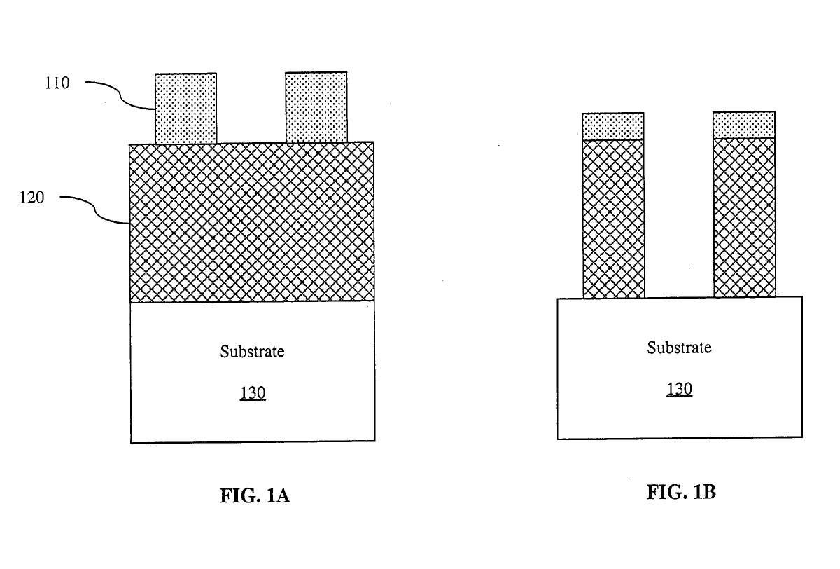

The present invention includes a BLR patterning process. FIG. 1A illustrates a BLR formed on a substrate or wafer 130 according to one embodiment of the present invention. The BLR includes a relatively thin upper resist layer (or image layer) 110 over a relatively thick lower resist layer (or mask layer) 120. In one exemplary embodiment of the present invention, the upper resist layer includes a silicon-rich polymer. The lower resist layer includes a resist material that is insensitive to light of certain wavelengths, such as 248 nm. Patterns including line and space patterns as shown in FIG. 1A in the upper resist layer 110 have been formed using conventional photolithography technology. The BLR patterning process of the present invention can be used to transfer the upper resist patterns to the lower resist layer 120, resulting in high aspect ratio lower resist mask patterns with vertical sidewalls 101, as shown in FIG. 1B.

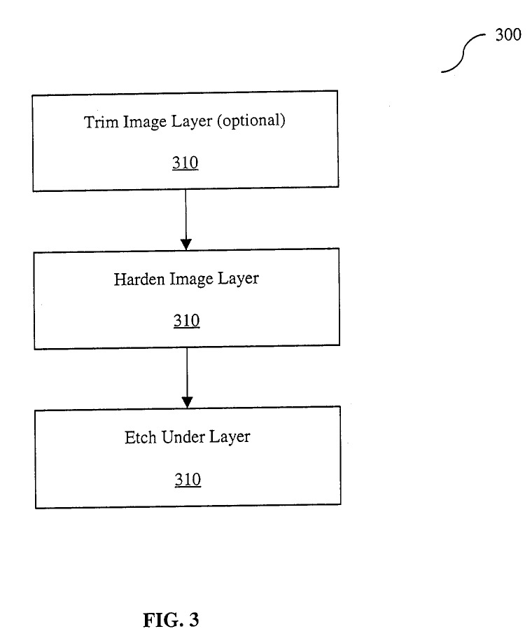

FIG. 3 is a flowchart illustrating a BLR patterning process (process) 300 according to one embodiment of the present invention. As shown in FIG. 3, process 300 includes an optional image layer trimming step 310, an image layer pre-etch treatment step 320, and a mask layer etching step 330.

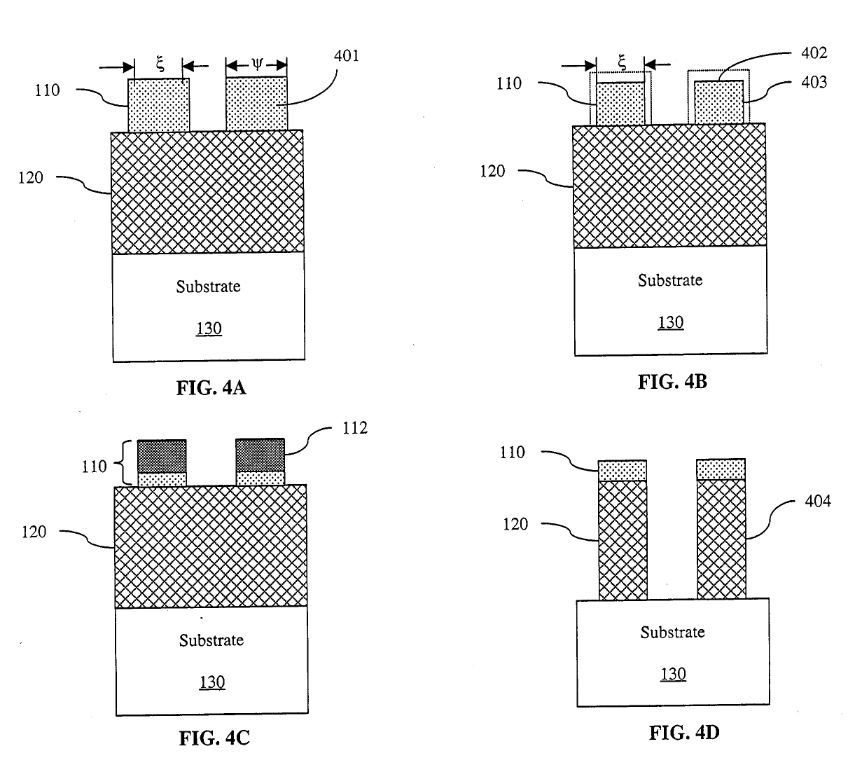

In the image layer trimming step, the patterned lines in the image layer 110 are trimmed, resulting in a CD shrinkage. As shown in FIG. 4A, after the image layer 110 is patterned, the CD ψ of the patterned lines 401 may be larger than a target CD ξ, and the difference between ψ and ξ, can vary from wafer to wafer. As shown in FIG. 4B, after the image layer trimming step 310, a CD shrinkage of (ψ-ξ) is reached to conform with the target CD and to reduce or eliminate wafer to wafer CD variations. Step 310 in process 300 is optional because in some applications, the difference between ψ and ξ or the wafer to wafer CD variation may be insignificant so that trimming is not required.

In the image layer pre-etch treatment step 320, as shown in FIG. 4C, the image layer 110, or a top part 112 of the image layer 110, is pre-etch treated to enhance its resistance to etching during the subsequent mask layer etching step 330.

In the mask layer etching step 330, the mask layer 120 is etched using the image layer 110 as a mask so that the image layer pattern is transferred to the mask layer 120, as shown in FIG. 4D.

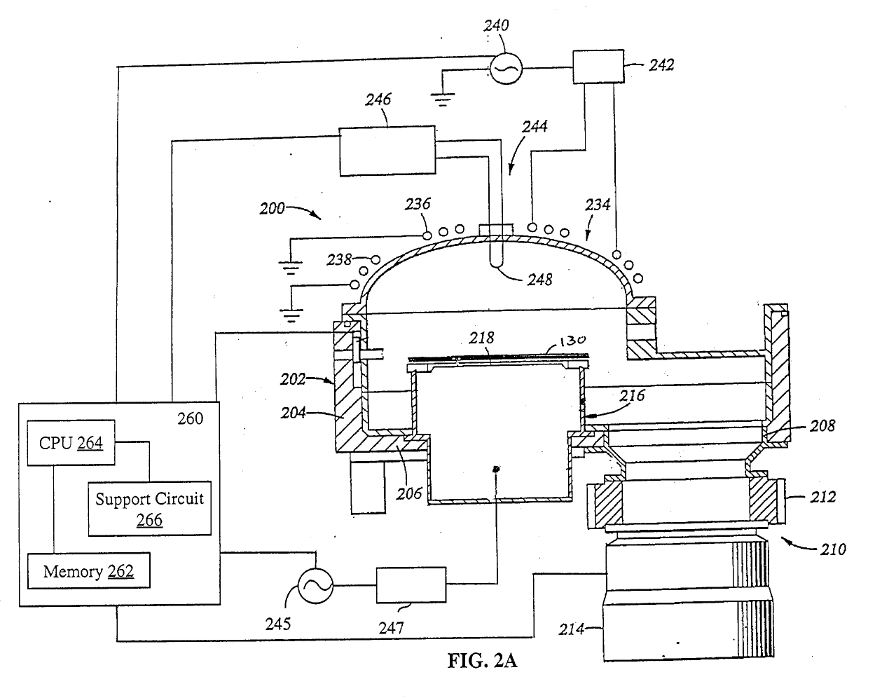

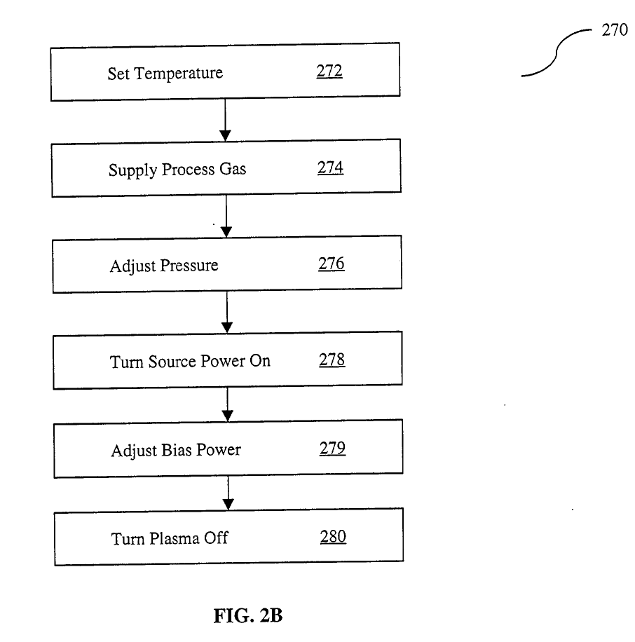

In one embodiment of the present invention, each of the image layer trimming step 310, the image layer treatment step 320 and the mask layer etching step 320 includes a plasma process in which the BLR on substrate 130 is exposed to a plasma, comprising energetic and reactive species. The plasma is usually generated by energizing a process gas in a plasma reactor, such as, for example, a decoupled plasma source (DPS) reactor, or a DPS II reactor, both being available from Applied Materials, Inc., in Santa Clara, Calif. A brief description of the DPS II reactor is provided below in connection with a schematic diagram of the DPS II reactor shown in FIG. 2A. More details about the DPS II reactor can be found in U.S. patent application Ser. No. 09/611,817 filed on Jul. 7, 2000, and also in U.S. patent application Ser. No. 09/544,377 filed on Apr. 6, 2000, both being incorporated by reference herein.

Referring to FIG. 2A, the DPS II reactor (reactor) 200 includes a process chamber (chamber) 202 having a chamber wall 204 and a chamber bottom 206. The chamber wall 204 extends substantially perpendicularly from the edge of the chamber bottom 206. The chamber bottom 206 includes an outlet 208 for exhausting gases from the chamber. An exhaust system 210 is attached to the outlet 208 of the chamber bottom 206.

A substrate support 216 is also disposed on the chamber bottom 206. The substrate support 216 may be an electrostatic chuck, a vacuum chuck or other wafer holding mechanisms, and includes a substrate supporting surface 218 on which the wafer or substrate 130 can be placed for processing. The substrate supporting surface 218 may be thermally connected to a substrate temperature control system (not shown), such as a resistive heating coil and/or fluid passages connected to a heating or cooling fluid system.

A chamber lid 234 is sealingly disposed above the chamber wall 204 to provide an enclosed environment inside the chamber for vacuum processing. The chamber lid may be shaped as a plate or a dome depending on the process for which the chamber is configured and the desired processing parameters. In the embodiment shown in FIG. 2, the chamber lid is dome-shaped. A coil antenna comprising one or more RF coils is wound around the dome-shaped lid. In the embodiment shown in FIG. 2, two coil loops 236, 238 are wound around a common axis of symmetry coincident with the axis of symmetry of the dome-shaped lid 234 and the axis of symmetry of the substrate supporting surface 218. The first RF coil 238 is wound around a bottom portion of the dome-shaped lid 234 while the second RF coil 236 is positioned centrally above the lid 234.

The first and second RF coils 236, 238 are connected to a first RF power supply (source power) 240 through an RF power distribution network 242. A second RF power supply (bias power) 245 is connected to the substrate support 216 through an RF impedance match network 247.

A gas distributor 244 is fluidly connected to a gas source 246 containing various gaseous components. As shown in FIG. 2, the gas distributor 244 may include one or more gas injection nozzles 248 disposed through a central top portion of the chamber lid 234.

When reactor 200 is used to perform one of the steps in process 300, the substrate 130 with the BLR formed thereon is placed on the substrate supporting surface 218 and gaseous components are introduced into the chamber 202 through gas injection nozzle 248 to form a process gas in the chamber 202. A volumetric flow rate of each gaseous component may be individually controlled by the gas distributor 244. Gas pressure in the chamber 202 is controlled using the vacuum pump 214 and the throttle valve 212. A plasma is ignited in the chamber 202 by turning on the source power 240. The bias power 245 may be adjusted to obtain a proper level of electrical bias between the substrate 130 and the plasma.

A controller 260 comprising a central processing unit (CPU) 264, a memory 262, and support circuits 266 for the CPU 264 is coupled to the various components of the reactor 200 to facilitate control of the BLR patterning process of the present invention. The memory 262 can be any computer-readable medium, such as random access memory (RAM), read only memory (ROM), floppy disk, hard disk, or any other form of digital storage, local or remote to the reactor 200 or CPU 264. The support circuits 266 are coupled to the CPU 264 for supporting the CPU in a conventional manner. These circuits include cache, power supplies, clock circuits, input/output circuitry and subsystems, and the like.

FIG. 2A only shows one exemplary configuration of various types of plasma reactors that can be used to practice the present invention, including, for example, inductively coupled plasma (ICP) reactors, electron-cyclotron reactors (ECR), triode reactors, and the like.

FIG. 2B is a flow chart illustrating a process sequence (sequence) 270 for performing the plasma process in each of the image layer trimming step 310, the image layer treatment step 320 and the mask layer etching step 320, using the reactor 200, according to one exemplary embodiment of the present invention. The sequence 270 includes step 272, in which the substrate temperature is set and further maintained at a predetermined value by controlling the flow of the backside helium gas.

The sequence 270 further includes step 274, in which gaseous components are supplied into the process chamber 202 to form the process gas. The sequence 270 further includes step 276, in which the pressure of the process gas in the process chamber 202 is adjusted by regulating a position of the throttle valve 212.

The sequence 270 further includes step 278, in which the source power 240 is turned on to ignite the process gas in processing chamber 202 to form the plasma. Thereafter or about simultaneously with igniting the plasma, at step 279 in the process sequence 270, the RF bias power 245 is adjusted to electrically bias the wafer support pedestal with respect to the plasma. With the RF bias power 245 on, a significant DC electrical potential difference (or DC voltage) may exist between the plasma and the wafer support 216, and most of this DC voltage appears across a thin sheath region near the substrate 130. Positive ions coming from the plasma are thus accelerated in the sheath region, and impinge on the substrate 130 with a significant amount of energy and directionality. The energetic and directional ions facilitate anisotropic etching. When such anisotropy is not required or when high energy ion impingement is not desired, as in the case of some plasma processes, the RF bias power may be set at a low value or completely turned off during the plasma process.

After the BLR on substrate 130 has been exposed to the plasma for a predetermined process time, or after a conventional endpoint detector indicates enough processing has been performed, at step 280 in the process sequence 270, the plasma is turned off by turning off both the source power 240 and the bias power 245.

The foregoing steps of the sequence 270 need not be performed sequentially, e.g., some or all of the steps may be performed simultaneously or in different order. In one embodiment of the present invention, sequence 270 is performed by the controller 260 as shown in FIG. 2A according to program instructions stored in memory 262. Alternatively, some or all of the steps in the sequence 270 may be performed in hardware such as an application-specific integrated circuit (ASIC) or other type of hardware implementation, or a combination of software or hardware.

In the image layer trimming step 310, the image layer 110 is trimmed using a plasma trimming process. In one embodiment of the present invention, the plasma trimming process is performed by exposing the image layer 110 to a plasma in the reactor 200 shown in FIG. 2A, according to the process sequence 270 described above in connection with FIG. 2B. During the plasma trimming process, the plasma typically removes the upper resist layer 110 more from a top surface 402 than from a sidewall 403, as shown in FIG. 4B, resulting in two different trimming rates, a vertical trimming rate and a horizontal trimming rate. The vertical trimming rate is defined as the rate at which the upper resist layer 110 is removed from a top surface of a patterned line, such as surface 402. The horizontal trimming rate is defined as the rate at which the upper resist layer 110 is removed from a sidewall of a patterned line, such as sidewall 403. It is usually desired that the vertical trimming rate and the horizontal trimming rate are as close to each other as possible. It is also desired that the plasma trimming process has good linearity, i.e., the trimming rates, especially the horizontal trimming rate, stays constant with time as trimming proceeds until the target CD is reached. Furthermore, it is desired that the trimming rates are uniform across the wafer so that the trimming step does not generate CD non-uniformity across the wafer.

In one embodiment of the present invention, the process gas used in the plasma trimming process includes O₂, which is a main resist etchant. The process gas further includes a bromine-containing gas and a fluorine-containing gas. Suitable bromine-containing gas includes HBr, CH₂Br₂ and CH₃Br, of which HBr is more often used. Suitable fluorine-containing gas includes SF₆, SF₄, S₂F₂, S₂F₁₀, NF₃, etc. of which SF₆ is more often used. The fluorine-containing gas contributes fluorine-containing species in the plasma that remove the silicon in the upper resist layer 110 and prevent it from reacting with O₂ to form SiO₂-like materials, which can act as protective shells at exposed surfaces of the upper resist layer 110. The bromine containing gas helps to provide passivation and to reduce the difference in trimming rate between dense and isolated areas. The process gas may further include Cl₂, which helps to improve upper resist sidewall smoothness.

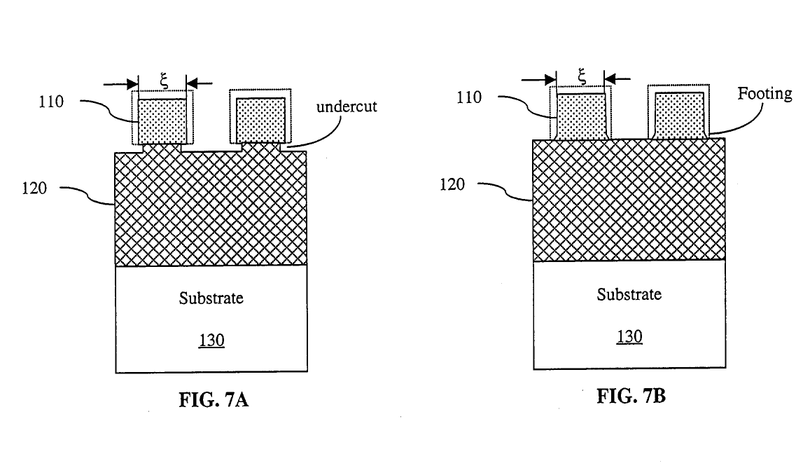

To ensure proper trimming of the upper resist layer 110, the volumetric flow rate of each gaseous component in the process gas needs to be controlled within a proper range. For example, increasing the flow rate of HBr or O₂ usually results in a faster trimming rate, but further increase in the flow rate of HBr and O₂ may cause etching of the lower resist layer and/or undercutting at the interface of the upper and lower resist layers, as shown in FIG. 7A. On the other hand, too high a flow rate of Cl₂ can result in footing at the bottom of the upper resist layer, as shown in FIG. 7B. The ranges (i.e., minimum and maximum values) and exemplary values of the flow rates for the gaseous components in the process gas for the plasma trimming process are listed in Table I, according to one embodiment of the present invention.

Additionally, to ensure proper trimming of the upper resist layer 110, the source power, the bias power and the gas pressure in the chamber 202 also need to be controlled within proper ranges. For example, in one embodiment of the present invention, lower pressure has been found to result in improved trimming selectivity to the lower resist layer. High source power has been found to increase trimming rates and to reduce the difference between vertical and horizontal trimming rates. But the increase in the bias power usually causes more resist loss from the top surface of the upper resist layer and a bigger difference between the vertical and horizontal trimming rates. In order to keep the difference between the vertical and horizontal trimming rates small, it is desired that no substantial DC bias exist between the substrate support 216 and the plasma in the reactor 200. Thus low pressure, high source power, and low or no bias power are used in one embodiment of the present invention. The ranges and exemplary values of the pressure, source power, and bias power used in the plasma trimming process are also listed in Table I, according to one embodiment of the present invention.

TABLE I

| Process Parameters | | | Minimum | Maximum | Example |
|---|---|---|---|---|---|
| | Process | HBr | 0 | 200 | 90 |
| | Gas (sccm) | SF₆ | 5 | 50 | 10 |
| | | O₂ | 5 | 20 | 5 |
| | | Cl₂ | 0 | 100 | 45 |

| | | | |
|---|---|---|---|
| Source Power (W) | 200 | 1500 | 800 |
| Bias Power (W) | 0 | 50 | 0 |
| Chamber Pressure (mTorr) | 4 | 20 | 4 |
| Wafer Pedestal Temperature (° C.) | 20 | 80 | 50 |

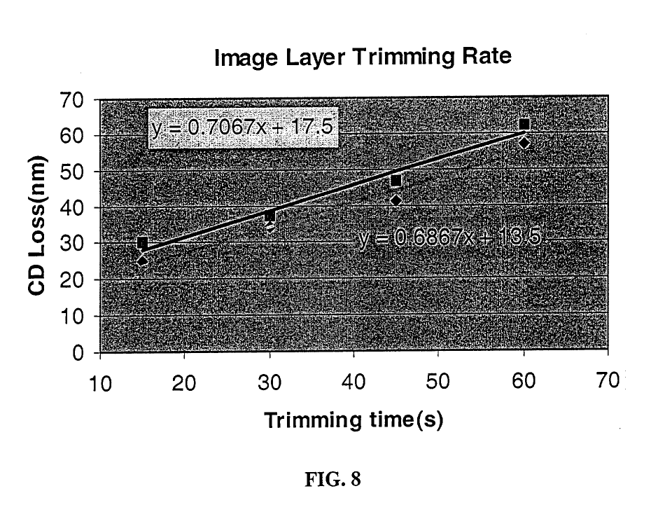

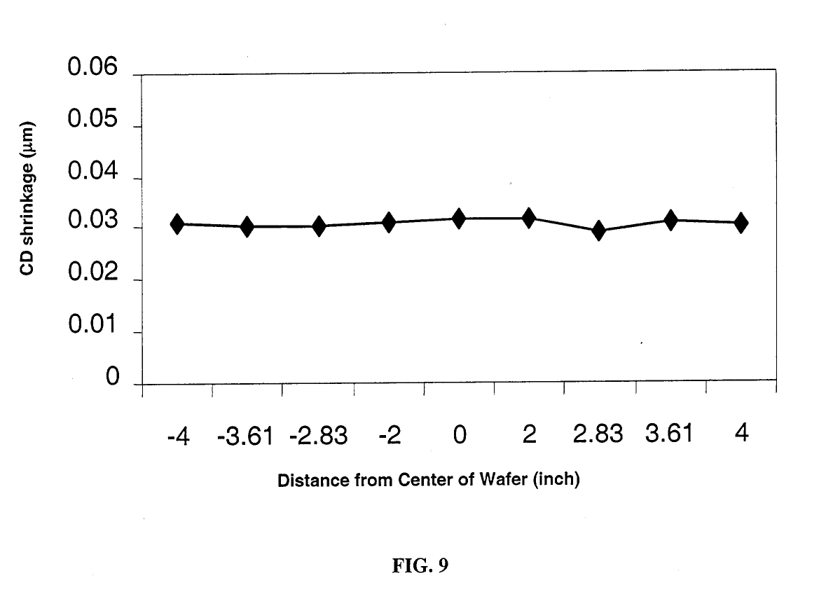

The plasma trimming process of the present invention has several advantages over conventional resist trimming processes. FIG. 8 plots CD shrinkage data taken from test wafers that have been subjected to an exemplary trimming process of the present invention for different lengths of time. As shown in FIG. 8, the trimming process of the present invention exhibits good linearity, i.e., the CD shrinkage varies linearly with the trimming time, or, the trimming rate, which is about 0.7 nm/sec in this example, stays constant as trimming proceeds, up to a CD shrinkage of about 60 nm. The linearity of the trimming process ensures accurate control of the trimming step, so that the target CD can be reached by simply setting the trimming time according to the amount of CD shrinkage required. The trimming process of the present invention also exhibits excellent trimming uniformity. As shown in FIG. 9, the amount of CD shrinkage is nearly constant across an 8-inch (or 200 mm) substrate 130. Furthermore, the trimming process of the present invention produces almost no roughness on the patterned line sidewalls, such as sidewall 403, due partly to the addition of Cl₂ to the HBr/O₂/SF₆ trimming chemistry.

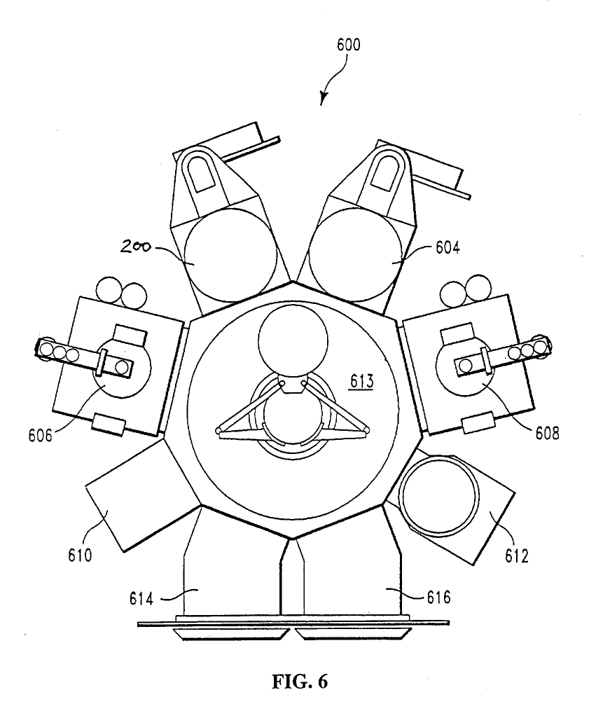

The performance of the image layer trimming step 310 can be controlled by the controller 260 according to program instructions stored in the memory 262 in the controller 260. In one embodiment of the present invention, the reactor 200 and the controller 260 are part of a cluster system 600 including the reactor 200 and a conventional CD measurement tool 610, as shown in FIG. 6. The cluster system 600 further includes a substrate orienter 612 and one or more loadlocks 614 and 616 for transferring substrates between the reactor 200 and the CD measurement tool 610. A robot arm 613, also controlled by the controller 260, facilitates transferring the substrate among the reactor 200, the CD measurement tool 610 and the loadlock(s) in the cluster system 600. The cluster system 600 may include another reactor 604 and resist stripping tools 606 and 608, which should not affect the practice of the present invention.

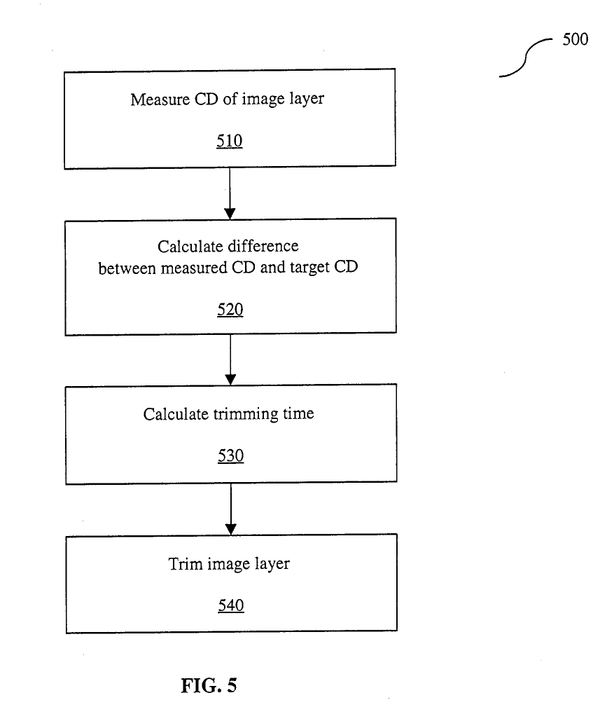

FIG. 5 illustrates a process 500 for performing the image layer trimming step 310 in the cluster system 600, according to one embodiment of the present invention. As shown in FIG. 5, process 500 includes step 510 in which an actual CD ψ of the image layer on substrate 130 is measured using the CD measurement tool 610. The measured CD data is output to the controller 260. Process 500 further includes step 520 in which the CPU 264 in the controller 260 calculates the difference between the measured CD and the target CD ξ, which has been stored in the memory 262. Process 500 further includes step 530 in which a trimming time is calculated, according to experimental data as shown in FIG. 7. Process 500 further includes step 540 in which the plasma trimming process as described above is performed to trim the image layer 110 according to the calculated trimming time.

In the image layer pre-etch treatment step 320, the image layer 110 is pre-etch treated using a plasma pre-etch treatment process. In one embodiment of the present invention, the plasma pre-etch treatment process is performed by exposing the image layer 110 to a plasma in reactor 200, according to the process sequence 270 described above in connection with FIG. 2B. The process gas used in the plasma pre-etch treatment process includes O₂ and/or N₂, which contributes to oxygen and/or nitrogen radicals that react with the silicon precursors in the upper resist layer 110 to form SiO₂-like and/or Si₃N₄-like products. The process gas may further include chlorine, which helps to maintain a smooth image layer surface by removing possible aggregated silicon formed thereon during the pre-etch treatment process. The addition of Cl₂ also results in significant reduction of the amount of undercutting of the mask layer near the interface between the image layer and the mask layer.

The process gas used in the plasma pre-etch treatment process further includes an inert gas, such as argon, neon, xenon, and krypton, of which argon (or Ar) is more often used. Ar contributes Ar ions in the plasma, which bombard the image layer 110 to help the oxygen and/or nitrogen radicals penetrate deeper into the image layer 110. To enable the argon-assisted oxygen and/or nitrogen penetration, a certain amount of bias power that creates a substantial DC bias between the substrate support 216 and the plasma in reactor 200 is helpful. The DC bias may fall in the range of a few tens of volts to a few hundred volts. In one exemplary embodiment of the present invention, the DC bias is about 100 V. Thus, with the addition of Ar, a thicker etch-resistant layer 112 can be formed at the top of the image layer 110, as shown in FIG. 4C. The addition of the inert gas also help to dilute the O₂ and/or N₂ components in the process gas to reduce the amount of etching into the lower-resist layer 120. The ranges (i.e., minimum and maximum values) and exemplary values of several process parameters for the plasma trimming process are listed in Table II, according to one embodiment of the present invention.

TABLE II

| Process Parameters | | | Minimum | Maximum | Example |
|---|---|---|---|---|---|
| | Process | O₂ | 10 | 200 | 50 |
| | Gas (sccm) | Ar | 0 | 200 | 50 |
| | | N₂ | 5 | 100 | 20 |
| | | Cl₂ | 5 | 50 | 20 |

| | | | |
|---|---|---|---|
| Source Power (W) | 200 | 1000 | 600 |
| Bias Power (W) | 20 | 100 | 40 |
| Chamber Pressure (mTorr) | 4 | 30 | 16 |
| Wafer Pedestal Temperature (° C.) | 20 | 80 | 50 |

The process time for which the image layer 110 is pre-treated depends on specific applications. Longer process time results in a thicker etch resistant layer 112, but may also result in too much etching of the lower resist layer 120 and undercutting at the interface between the upper and lower resist layers.

In the mask layer etching step 330, the mask layer 120 is etched using a plasma etching process. In one embodiment of the present invention, the plasma etching process is performed by exposing uncovered portions of the mask layer 110 to a plasma in reactor 200, according to the process sequence 270 described above in connection with FIG. 2B. The process gas used in the plasma etching process includes O₂, which is a main etchant. The process gas further includes bromine-containing gas, such as HBr, CH₂Br₂ and CH₃Br, which provides sidewall passivation to prevent lateral etching of the lower resist layer by O₂. The process gas may further include N₂, which provides passivation and prevents resist undercutting of the upper portion of the lower resist layer. The process gas may further include an inert gas, such as argon, helium, neon, xenon, and krypton, of which argon (or Ar) is more often used. Ar contributes Ar ions in the plasma, which bombard the lower resist layer 120 to produce higher etch rate and to make the etching of the lower resist layer proceed more vertically.

In order to achieve optimum etching profiles in the lower resist layer 120, process parameters such as gas flow rates, chamber pressure, etc., need to be controlled within proper ranges, according to specific applications. In one embodiment of the present invention, increasing the flow rate of HBr results in reduced lateral etching, but too high a HBr flow rate may produce a tapered sidewall profile. Also, increasing the flow rate of O₂ usually results in increased etch rate of the lower resist layer, but too high an O₂ flow rate produces undercutting at the interface between the upper and lower resist layers. Furthermore, increasing Ar flow rate and/or the bias power increases Ar bombardment on the BLR and as a result, a higher etch rate in the lower resist layer. But excess Ar bombardment reduces selectivity between the upper and lower resist layers. Moreover, higher gas pressure in the chamber 202 has been observed to produce better etching selectivity to the upper resist layer 110, but sidewall bowing may result when the gas pressure is too high. The ranges (i.e., minimum and maximum values) and exemplary values of several process parameters for the plasma trimming process are listed in Table III, according to one embodiment of the present invention.

TABLE III

| Process Parameters | | | Minimum | Maximum | Example |
|---|---|---|---|---|---|
| | Process | HBr | 20 | 200 | 130 |
| | Gas (sccm) | N₂ | 0 | 50 | 35 |
| | | O₂ | 5 | 20 | 14 |
| | | Ar | 0 | 100 | 32 |

| | | | |
|---|---|---|---|
| Source Power (W) | 200 | 1000 | 400 |
| Bias Power (W) | 40 | 150 | 80 |
| Chamber Pressure (mTorr) | 4 | 30 | 16 |
| Wafer Pedestal Temperature (° C.) | 20 | 80 | 50 |

The mask layer plasma etching process of the present invention has several advantages over prior art mask layer etching processes. Instead of the corrosive SO₂ gas the mask layer etching process uses HBr or HBr/N₂ combination, which are provided by many plasma etching systems and which do not cause corrosion in these plasma etching systems. The HBr and N₂ components in the process gas have been found to offer sufficient sidewall protection so that the substrate 130 does not have to be maintained at low temperature in order to prevent undercutting or lateral etching of the lower resist layer 120. In one embodiment of the present invention, the substrate temperature can be as high as 50° C. and still no undercutting or lateral etching of the lower resist layer 120 is observed. Furthermore, the mask layer etching process of the present invention does not generate roughness on the sidewalls (such as sidewall 404 in FIG. 4D) of etched mask layer patterns.

In one embodiment of the present invention, the performance of process 300 is controlled by the CPU 264 in the controller 260 according to program instructions stored in the memory 262.

Because the actual process parameters, such as the source power, bias power, pressure, gas flow rates, etc., are dependent upon the size of the wafer, the specific type of resist films formed on the wafer, the volume of the chamber 202, and on other hardware configurations of the reactor 200, the invention is not limited to process parameters or the ranges recited herein.

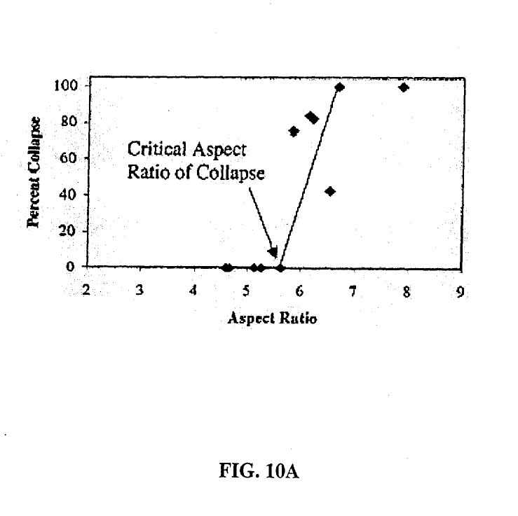

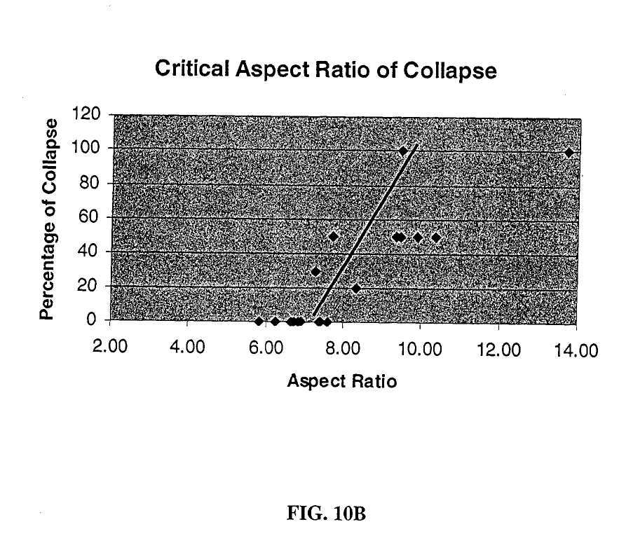

Thus the present invention provides a BLR patterning process that enables proper patterning of high aspect ratio BLR films using plasma processing techniques. The advantages of BLR films and the BLR patterning process of the present invention are numerous. In addition to the ones recited above, the BLR patterning process of the present invention avoids wet developing of high aspect ratio resist patterns, resulting in an improved critical aspect ratio of collapse (CARC). The CARC is defined as the aspect ratio achievable in a resist film before collapsing of a significant portion of the patterned resist occurs. Because of the involvement of processes such as wet developing in conventional resist patterning techniques, capillary effect during subsequent rinsing and external forces induced during spin-dry typically result in CALC occurring at a lowaspect ratio, such as 5:1 or even 4:1, as shown in FIG. 10A. So the conventional resist patterning processes can only use a resist thickness of up to 3600 Å for 90 nm line width or a resist thickness of up to 2400 Å for 60 nm line width. In contrast, the BLR patterns produced by the BLR patterning processes in one embodiment of the present invention have CALC occurring at 7:1 aspect ratio, as shown in FIG. 10B. This allows a maximum resist thickness of about 5400 Å for 90 nm line width or a maximum resist thickness of about 3600 Å for 60 nm line width. A significant improvement in CALC performance is thus achieved using the BLR resist patterning process of the present invention.

While the present invention has been described with reference to a few specific embodiments, the description is illustrative of the invention and is not to be construed as limiting the invention. Various modifications may occur to those skilled in the art without departing from the true spirit and scope of the invention as defined by the appended claims.

What is claimed is:

1. A method for patterning a bilayer resist formed on a substrate, the bilayer resist comprising a patterned upper resist layer over a lower resist layer, the method comprising:
trimming the upper resist layer in a plasma of a first process gas;
treating the trimmed upper resist layer in a plasma of a second process gas; and
etching the lower resist layer in a plasma of a third process gas using the treated upper resist layer as a mask, the third process gas being different from the second process gas.

2. The method of claim 1 wherein the first process gas comprises oxygen and a fluorine-containing gas selected from the group consisting of SF₆, SF₄, S₂F₂, S₂F₁₀, and NF₃.

3. The method of claim 2 wherein the first process gas further comprises a bromine-containing gas selected from the group consisting of HBr, CH₃Br, and CH₂Br₂.

4. The method of claim 2 wherein the first process gas further comprises a chlorine-containing gas selected from the group consisting of Cl₂ and HCl.

5. The method of claim 1 wherein the substrate is placed on a pedestal in a plasma etch chamber, and wherein trimming the upper resist layer comprises maintaining a plasma of the first process gas in the plasma etch chamber such that no substantial DC bias exists between the pedestal and the plasma of the first process gas.

6. The method of claim 1 wherein the second process gas comprises O₂ or N₂ or their combination.

7. The method of claim 6 wherein the second process gas further comprises an inert gas selected from the group consisting of argon, neon, xenon, and krypton.

8. The method of claim 6 wherein the second process gas further comprises a chlorine-containing gas selected from the group consisting of Cl₂ and HCl.

9. The method of claim 1 wherein the substrate is placed on a pedestal in a plasma etch chamber, and wherein treating the trimmed upper resist layer comprises maintaining a plasma of the second process gas in the plasma etch chamber such that a substantial DC bias exists between the pedestal and the plasma of the second process gas.

10. The method of clam 1 wherein the third process gas comprises O₂ and a bromine-containing gas selected from the group consisting of HBr, CH₃Br, and CH₂Br₂.

11. The method of claim 10 wherein the third process gas further comprises N₂.

12. The method of claim 10 wherein the third process gas further comprises an inert gas selected from the group consisting of helium, argon, neon, xenon, and krypton.

13. A method of trimming a resist layer in a plasma chamber, comprising:
introducing into the plasma chamber a process gas including O₂, a bromine-containing gas selected from the group consisting of HBr, CH₃Br, and CH₂Br₂, and a fluorine-containing gas selected from the group consisting of SF₆, SF₄, S₂F₂, S₂F₁₀, and NF₃; and
maintaining a plasma of the process gas in the plasma chamber to trim the resist layer.

14. The method of claim 13 wherein the resist layer is formed on a substrate placed on a pedestal in the plasma etch chamber, and wherein the plasma of the process gas is maintained such that no substantial DC bias exists between the plasma and the pedestal.

15. The method of claim 13 wherein the process gas further includes chlorine-containing gas selected from the group consisting of Cl₂ and HCl.

16. The method of claim 13 wherein the plasma of the process gas is maintained for a period of time determined from a difference between a target critical dimension and a measured critical dimension.

17. The method of claim 13 wherein the period of time is linearly related to the difference between the target critical dimension and the measured critical dimension.

18. A method of treating a silicon-containing resist layer to increase its resistance to a subsequent etching process that etches a layer of material under the resist layer, comprising:
introducing into a plasma chamber in which the silicon-containing resist layer is situated a process gas including O₂ and an inert gas selected from the group consisting of argon, neon, xenon, and krypton; and
maintaining a plasma of the process gas in the plasma chamber to treat the silicon-containing resist layer.

19. The method of claim 18 wherein the process gas further includes N₂.

20. The method of claim 18 wherein the process gas further comprises a chlorine-containing gas selected from the group consisting of Cl₂ and HCl.

21. The method of claim 18 wherein the silicon-containing resist layer is formed on a substrate placed on a pedestal in the plasma etch chamber, and wherein the plasma of the process gas is maintained such that a substantial DC bias exists between the plasma and the pedestal.

22. A method of etching a resist layer, comprising:
introducing into a plasma chamber in-which the resist layer is situated a process gas including O₂ and a bromine-containing gas selected from the group consisting of HBr, CH₂Br₂ and CH₃Br; and
maintaining a plasma of the process gas in the plasma chamber to etch the resist layer.

23. The method of claim 22 wherein the process gas further includes N₂.

24. The method of claim 22 wherein the process gas further includes an inert gas selected from the group consisting of helium, argon, neon, xenon, and krypton.

25. A computer readable medium storing therein program instructions that when executed by a computer cause an etch reactor to pattern a bilayer resist layer formed on a substrate, the bilayer resist layer comprising a patterned upper resist layer over a lower resist layer, the program instructions comprising instructions for:
trimming the upper resist layer in a plasma of a first process gas;
treating the trimmed upper resist layer in a plasma of a second process gas; and
etching the lower resist layer in a plasma of a third process gas using the treated upper resist layer as a mask, the third process gas being different from the second process gas.

26. A computer readable medium storing therein program instructions that when executed by a computer cause a plasma reactor to trim a resist layer, the program instructions comprising instructions for:
introducing into the plasma reactor a process gas including O₂, a bromine-containing gas selected from the group consisting of HBr, CH₃Br, and CH₂Br₂, and a fluorine-containing gas selected from the group consisting of SF₆, SF₄, S₂F₂, S₂F₁₀, and NF₃; and
maintaining a plasma of the process gas in the plasma reactor to trim the resist layer.

27. A computer readable medium storing therein program instructions that when executed by a computer cause a plasma reactor to treat a silicon-containing resist layer to increase its resistance to a subsequent etching process that etches a layer of material under the resist layer, the program instructions comprising instructions for:
introducing into the plasma reactor a process gas including O₂ and an inert gas selected from the group consisting of argon, neon, xenon, and krypton; and
maintaining a plasma of the process gas in the plasma reactor to treat the silicon-containing resist layer.

28. A computer readable medium storing therein program instructions that when executed by a computer cause an etch reactor to etch a resist layer, the program instructions comprising instructions for:
introducing into the etch reactor a process gas including O₂ and a bromine-containing gas selected from the group consisting of HBr, CH₂Br₂ and CH₃Br; and
maintaining a plasma of the process gas in the etch reactor to etch the resist layer.

29. A computer readable medium storing therein program instructions that when executed by a computer cause a cluster system to trim a resist layer formed on a substrate, the cluster system comprising an etch reactor and a critical dimension (CD) measurement tool, the program instructions comprising instructions for:
placing the substrate in the CD measurement tool;
measuring a CD of the resist layer using the CD measurement tool;
determining a trimming time based on a difference between a target CD and the measured CD;
placing the substrate in the etch reactor;
introducing into the etch reactor a process gas including O₂, a bromine-containing gas selected from the group consisting of HBr, CH₃Br, and CH₂Br₂, and a fluorine-containing gas selected from the group consisting of SF₆, SF₄, S₂F₂, S₂F₁₀, and NF₃; and
maintaining a plasma of the process gas in the etch reactor for the trimming time.

30. A method for patterning a bilayer resist formed on a substrate, the bilayer resist comprising a patterned upper resist layer over a lower resist layer, the method comprising:
trimming the upper resist layer in a plasma of a first process gas, the first process gas comprising oxygen, a fluorine-containing gas selected from the group consisting of SF₆, SF₄, S₂F₂, S₂F₁₀, and NF₃, and a bromine-containing gas selected from the group consisting of HBr, CH₃Br, and CH₂Br₂;
treating the trimmed upper resist layer in a plasma of a second process gas, the second process gas comprising O₂ or N₂ or their combination and further comprising an inert gas selected from the group consisting of argon, neon, xenon, and krypton; and
etching the lower resist layer in a plasma of a third process gas using the treated upper resist layer as a mask, the third process gas comprising O₂ and a bromine-containing gas selected from the group consisting of HBr, CH₃Br, and CH₂Br₂.

31. The method of claim 30 wherein the first process gas further comprises a chlorine-containing gas selected from the group consisting of Cl₂ and HCl.

32. The method of claim 30 wherein the substrate is placed on a pedestal in a plasma etch chamber, and wherein trimming the upper resist layer comprises maintaining a plasma of the first process gas in the plasma etch chamber such that no substantial DC bias exists between the pedestal and the plasma of the first process gas.

33. The method of claim 30 wherein the second process gas further comprises a chlorine-containing gas selected from the group consisting of Cl₂ and HCl.

34. The method of claim 30 wherein the substrate is placed on a pedestal in a plasma etch chamber, and wherein treating the trimmed upper resist layer comprises maintaining a plasma of the second process gas in the plasma etch chamber such that a substantial DC bias exists between the pedestal and the plasma of the second process gas.

35. The method of clam 30 wherein the third process gas further comprises N₂.

36. The method of claim 30 wherein the third process gas further comprises an inert gas selected from the group consisting of helium, argon, neon, xenon, and krypton.
